(19) United States
(12) Patent Application Publication
(10) Pub. No.: US 2025/0259819 A1
(43) Pub. Date: Aug. 14, 2025

(54) APPARATUS FOR PLASMA PROCESSING

(71) Applicant: Tokyo Electron Limited, Tokyo (JP)

(72) Inventor: Toshihiko Iwao, Nirasaki City (JP)

(21) Appl. No.: 18/436,543

(22) Filed: Feb. 8, 2024

(51) Int. Cl. H01J 37/32

(52) U.S. Cl. CPC H01J 37/3211; H01J 37/3244; H01J 37/32825; H01J 2237/327

(57) ABSTRACT

An apparatus for plasma processing includes an insulating structure including a showerhead and an antenna surrounding the showerhead. The antenna includes a plate of conductive material and a first slot through the plate of conductive material. The plate has a ring shape in a top view. The first slot has a longitudinal length that is a half wavelength of an excited frequency electromagnetic wave.

### TECHNICAL FIELD

The present invention relates generally to semiconductor processing technology and, in particular embodiments, to an antenna for plasma processing.

### BACKGROUND

Plasma processing is extensively used in the manufacturing and fabricating high-density microscopic circuits within the semiconductor industry. In a plasma processing system, an electromagnetic wave radiated into a plasma chamber generates an electromagnetic field. The generated electromagnetic field heats electrons in the chamber. The heated electrons ignite plasma that treats the substrate in a process such as for etching, deposit, oxidation, sputtering, or the like. Antennas are used to generate the plasma in the plasma chamber and may be capacitively coupled or inductively coupled to the plasma.

A non-uniform electromagnetic field within the plasma processing chamber results in a non-uniform plasma which in turn results in a non-uniform treatment of the substrate due to different portions of the substrate being treated with varying densities of plasma. An apparatus and system that improves the uniformity of the electromagnetic field in a plasma processing system are, thus, desirable. An antenna that does not need calibration or adjustment to maintain uniformity of the electromagnetic field is desirable to reduce maintenance cost.

### SUMMARY

In accordance with an embodiment, an apparatus for plasma processing includes: an insulating structure including a showerhead; and an antenna surrounding the showerhead, the antenna including: a plate of conductive material, the plate having a ring shape in a top view; and a first slot through the plate of conductive material, the first slot having a longitudinal length that is a half wavelength of an excited frequency electromagnetic wave in a range of 160 MHz to 240 MHz.

In accordance with another embodiment, an apparatus for plasma processing includes: a plasma processing chamber, the plasma processing chamber including: a substrate holder; a showerhead, the showerhead being over the substrate holder; an insulating structure, the insulating structure covering the showerhead; and a slot antenna plate, the slot antenna plate being mounted in the insulating structure, the slot antenna plate including a plurality of slots extending through the slot antenna plate; and a first radio frequency (RF) source, the first RF source coupled to the slot antenna plate through a sidewall of the insulating structure.

In accordance with yet another embodiment, a method for plasma processing includes: coupling RF power to a slot antenna plate mounted in an insulating structure, the insulating structure being a top portion of a plasma processing chamber; igniting a plasma in the plasma processing chamber with the RF power coupled through the slot antenna plate; and processing a substrate with the plasma.

It is to be understood that both the foregoing general description and the following detailed description are exemplary and explanatory only and are not restrictive of the disclosure, as claimed.

### BRIEF DESCRIPTION OF THE DRAWINGS

FIG. 1A illustrates an example plasma processing system, in accordance with some embodiments;

FIG. 1B illustrates another example plasma processing system, in accordance with some embodiments;

FIGS. 2A-2C illustrate top and perspective views of a slot antenna plate, in accordance with some embodiments;

FIG. 3 illustrates simulated results for sheath electric field for a plasma generated with a plasma processing system having a slot antenna plate, in accordance with some embodiments;

FIGS. 4A and 4B illustrate graphs of simulated results for plasma permittivity in plasma processing chambers, in accordance with some embodiments; and

FIG. 5 illustrates a process flow chart diagram of a method for plasma processing, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

While inventive aspects are described primarily in the context of radiating structures in a plasma processing system, the inventive aspects may be similarly applicable to fields outside the semiconductor industry. Plasma can be used to treat and modify surface properties through functional group addition. For example, to treat surfaces for paint deposit, plasma can convert hydrophobic surfaces to hydrophilic surfaces. Further, the inventive aspects are not limited to plasma. For example, RF can be used to thaw out frozen food or dry out textiles, food, wood, or the like. In these various examples and across industries, a uniform oscillating magnetic field as disclosed herein is advantageous.

According to one or more embodiments of the present disclosure, this application relates to systems and methods for very high frequency (VHF) plasma processing, and in particular embodiments, for a radial line slot antenna transmission line for diffusion plasma production. VHF plasma may tend to generate non-uniform plasma across a radial direction of a target, such as a semiconductor substrate (e.g., a wafer). However, conventional VHF electrode may have no access of metal lines for transmission of current to an electromagnetic coil. As such, it is advantageous to use a slot antenna (also referred to as a radial line slot antenna (RLSA)) plate coupled to a transmission line for diffusion plasma production.

The slot antenna plate may be placed near or around a showerhead for providing gas (such as plasma precursors) into a process chamber. In some embodiments, the slot antenna plate comprises a metal plate having slots cut through the plate. Longitudinal lengths of the slots are close to the half wavelength of an excited frequency electromagnetic wave within a media (e.g., a dielectric material such as an alumina or other ceramic insulator, air, or vacuum) that surrounds the metal plate. The slot antenna plate is able to couple to a conduction line and thereby reduce radial plasma non-uniformity from magnetic field generated by current from a conduction line coupled to an electromagnetic coil embedded in a powered electrode of other designs. As such, the slot antenna plate may be used for transmitting power (such as radiation for VHF band plasma) into the edge of the plasma generation region between the showerhead and chamber wall. This provides plasma uniformity controllability by the magnetic field generated by the current via the conduction line.

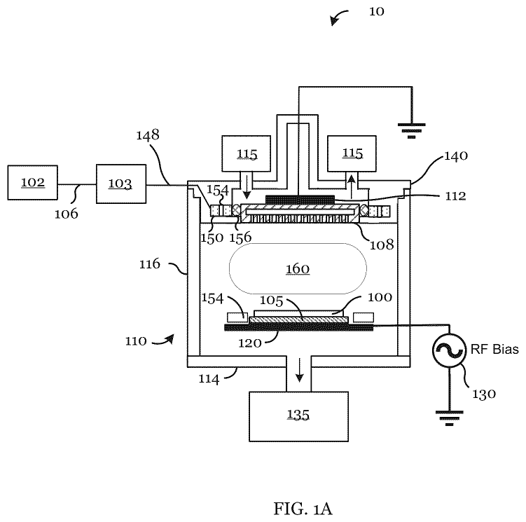

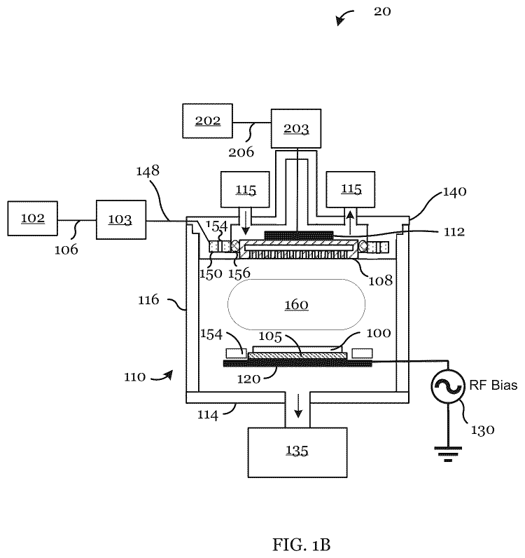

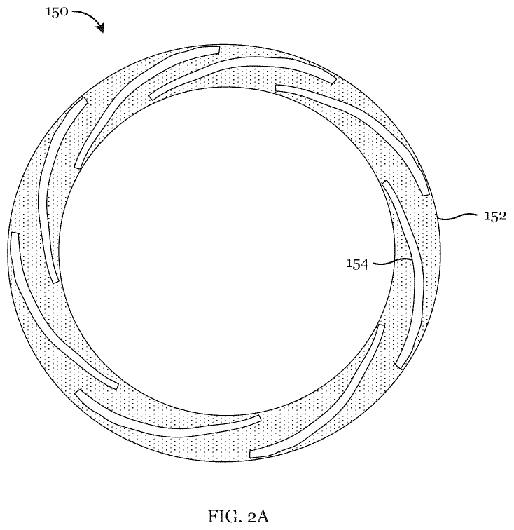

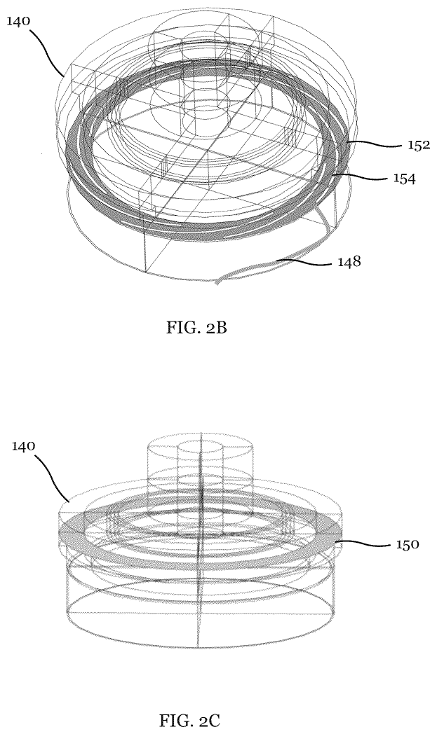

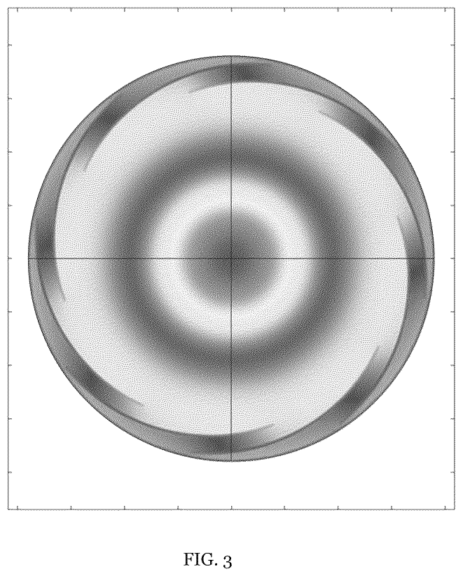

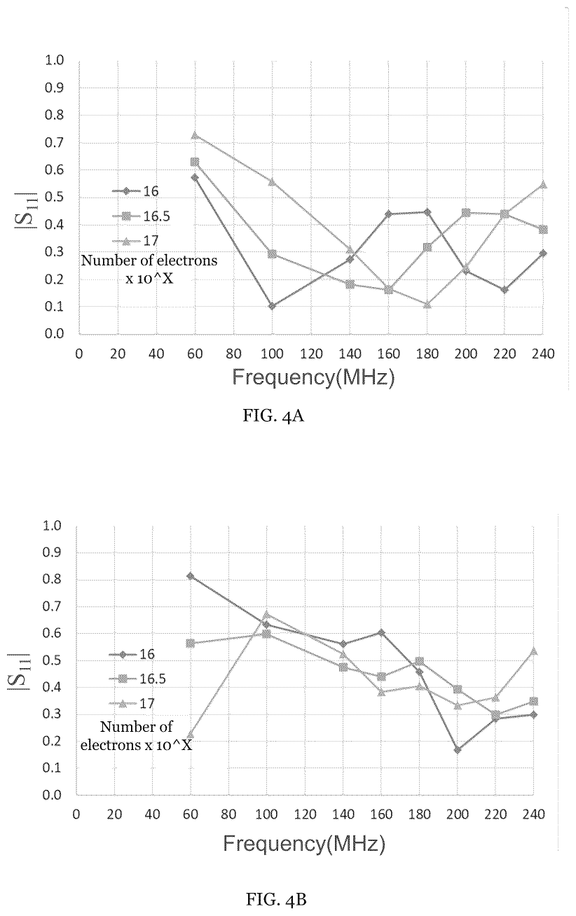

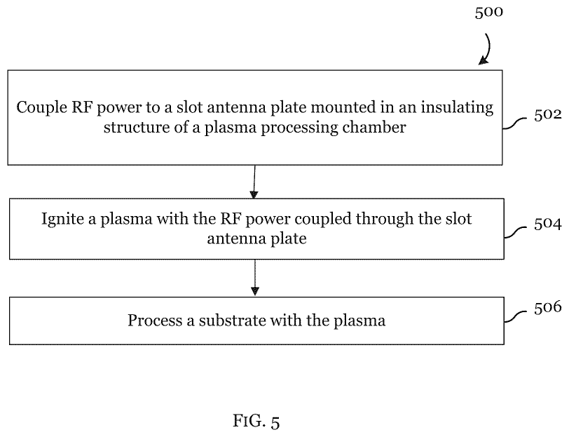

Embodiments of the disclosure are described in the context of the accompanying drawings. Embodiments of plasma processing systems will be described using FIGS. 1A and 1B. Embodiments of slot antenna plates will be described using FIGS. 2A, 2B, and 2C. Simulated results for sheath electric field for a plasma will be described using FIG. 3. Simulated results for plasma permittivity will be described using FIGS. 4A and 4B. An embodiment of a method for plasma processing will be described using FIG. 5.

FIG. 1A illustrates an example plasma processing system 10, in accordance with various embodiments. As illustrated in FIG. 1A, the plasma processing system 10 comprises a plasma processing chamber 110 with source power excitation and substrate bias power (in other words, wafer biasing capabilities). In other embodiments, substrate bias power may not be included in the plasma processing system.

A substrate 100 may be placed on a substrate holder 105. In various embodiments, the substrate 100 may be a part of, or including, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

In various embodiments, the plasma processing system 10 may further comprise a focus ring 164 positioned over the bottom electrode 120 to surround the substrate 100. The focus ring 164 may advantageously maintain and extend the uniformity of a plasma 160 to achieve process consistency at the edge of the substrate 100. In various embodiments, the focus ring 164 may have a width of a few cm. In various embodiments, there may be a gap for mechanical clearance between the circumference of the substrate 100 and the focus ring 164. In certain embodiments, the gap may be hundreds of microns to a few mm. In various embodiments, the focus ring 164 may comprise a dielectric material with a desired dielectric constant. In certain embodiments, the focus ring 164 may comprise silicon. Some examples of silicon-based focus ring may comprise silicon, silicon oxide, doped silicon (e.g., boron-doped, nitrogen-doped, and phosphorous-doped), or silicon carbide. Alternatively, in some embodiments, the focus ring may comprise a carbon-based material. In one or more embodiments, the focus ring 164 may comprise a metal oxide, such as aluminum oxide and zirconium oxide.

A process gas may be introduced into the plasma processing chamber 110 by a gas delivery system 115. The gas delivery system 115 may comprise multiple gas flow controllers to control the flow of multiple gases into the plasma processing chamber 110. For example, as illustrated by FIG. 1A, the gas delivery system 115 includes a gas inlet and a gas outlet at the top of the plasma processing chamber 110. However, the gas delivery system 115 may comprise any suitable numbers of gas inlets and gas outlets at any suitable positions.

Any precursors that can create a plasma may be used, such as argon (Ar), helium (He), tetrafluoromethane (CF₄), oxygen (O₂), an admixture of tetrafluoromethane and oxygen (CF₄/O₂), methane (NH₃), chlorine (Cl₂), hexafluorobutadiene (C₄F₆), octafluorocyclobutane (C₄F₈), nitrogen (N₂), hydrogen (H₂), hydrogen chloride (HCl), hydrogen bromide (HBr), the like, or any combination, or admixture thereof in any suitable ratio. In some embodiments, optional center/edge splitters may be used to independently adjust the gas flow rates at the center and edge of the substrate 100. In various embodiments, the total flow rate of the gas is in a range of 1 standard cubic centimeters per minute (secm) to 5000 secm, at a pressure in a range of 0.1 mTorr to 10 Torr, such as 100 mTorr, and/or at a temperature in a range of −200° C. to 500° C.

In various embodiments, the gas delivery system 115 comprises a special showerhead configuration positioned at the top of the plasma processing chamber 110. For example, the gas delivery system 115 may have a showerhead 108 covering the entirety of the substrate 100, including a plurality of appropriately spaced gas inlets. Alternatively, gas may be introduced through dedicated gas inlets of any other suitable configuration. The plasma processing chamber 110 may further be equipped with one or more sensors such as pressure monitors, gas flow monitors, and/or gas species density monitors. The sensors may be integrated as a part of the gas delivery system 115 in various embodiments.

In FIG. 1A, the plasma processing chamber 110 is a vacuum chamber and may be evacuated using one or more vacuum pumps 135, such as a single stage pumping system or a multistage pumping system (e.g. a mechanical roughing pump combined with one or more turbomolecular pumps). In order to promote even gas flow during plasma processing, gas may be removed from more than one gas outlet or location in the plasma processing chamber 110 (e.g., on opposite sides of the substrate 100). The plasma processing chamber 110 comprises a bottom plate 114, a side wall 116 over the bottom plate 114, and an insulating structure 140 over the side wall 116. The bottom plate 114 and the side wall 116 may be conductive and electrically coupled to the system ground (a reference potential). In some embodiments, the insulating structure 140 comprises a dielectric material such as alumina (A₂O₃, also referred to as aluminum oxide). However, the insulating structure 140 may comprise any suitable dielectric material.

In various embodiments, the substrate holder 105 may be integrated with, or a part of, a chuck (e.g., a circular electrostatic chuck (ESC)) positioned near the bottom of the plasma processing chamber 110, and connected to a bottom electrode 120. The surface of the chuck or the substrate holder 105 may be coated with a conductive material (e.g., a carbon-based or metal-nitride based coating). The substrate 100 may be optionally maintained at a desired temperature using a temperature sensor and a heating element connected to a temperature controller (not shown). In certain embodiments, the temperature sensor may comprise a thermocouple, a resistance temperature detector (RTD), a thermistor, or a semiconductor based integrated circuit. The heating element may for example comprise a resistive heater in one embodiment. In addition, there may be a cooling element such as a liquid cooling system coupled to the temperature controller. The bottom electrode 120 may be coupled to a RF bias power source 130.

Further in FIG. 1A, a top electrode 112 is above the showerhead 108. The top electrode 112 may be, for example, a conductive plate. However, any suitable top electrode 112 may be used. The top electrode 112 is coupled to a ground terminal (coupled to the system ground) located outside the plasma processing chamber 110 through the insulating structure 140. The top electrode 112 may receive transmitted power from a slot antenna plate 150 that is mounted in the insulating structure 140.

The slot antenna plate 150 may be mounted within the insulating structure 140. In various embodiments, the slot antenna plate 150 has a ring shape in a top view (see below, FIG. 2A). One or more slots 154 extend through the slot antenna plate 150. The slots 154 have longitudinal lengths that are close to the half wavelength of an excited frequency electromagnetic wave (e.g., 200 MHz to 240 MHz, such as 220 MHz) within the insulating structure 140 (e.g., a ceramic such as an alumina insulator) that surrounds the slot antenna plate 150. In other words, the wavelength of the excited frequency electromagnetic wave will be shortened in the dielectric material of the insulating structure 140 relative to the vacuum wavelength of the electromagnetic wave in the power transmission line 206, and the dimension of the slots 154 is based on this shortened wavelength.

In various embodiments, one or more vacuum seal(s) 156 (e.g., O-rings, although any suitable vacuum seals may be used) are disposed between the insulating structure 140 and slot antenna plate 150 and the interior of the plasma processing chamber 110 (including the gas delivery system 115 and the showerhead 108). As such, the slot antenna plate 150 (including the slots 154) is under atmospheric pressure while a vacuum is maintained in the interior of the plasma processing chamber 110. Although FIG. 1A illustrates one vacuum seal 156 between the slot antenna plate 150 and the showerhead 108, any suitable number of vacuum seals 156 may be used in any suitable locations, such as at a boundary between the insulating structure 140 and the side wall 116.

The plasma processing system 10 further includes a radio frequency (RF) source 102 (also referred to as a power source) and a matching network 103 that are coupled with the slot antenna plate 150. In various embodiments, the RF source 102 includes an RF power supply, which may include a generator circuit. The RF source 102 is coupled to the slot antenna plate 150 via a power transmission line 106, such as a coaxial cable or the like, a matching network 103, and a conduction line 148. In various embodiments, the RF source 102 is configured to supply VHF range power for plasma production, such as in a frequency range of 160 MHz to 240 MHz. However, any suitable frequency power (e.g., UHF, microwave, or the like) may be used.

The matching network 103 typically includes one or more capacitors and inductors. In embodiments, the capacitors and inductors may be variable. The forward and reflected power at the matching network 103 can be measured, and the matching network 103 may be adjusted to improve impedance matching. For example, a feedback loop circuit may be used to adjust the variable capacitors and inductors.

The conduction line 148 couples the slot antenna plate 150 to the matching network 103 through a sidewall of the insulating structure 140 and thereby delivers RF power from the RF source 102 to the slot antenna plate 150. This may be advantageous for reducing radial plasma non-uniformity from magnetic field generated by current from a conduction line coupled to, for example, the top electrode 112. As such, the conduction line 148 and the slot antenna plate 150 may be used for transmitting power (such as radiation for VHF band plasma) through the slots 154 to gases flowing through the showerhead 108 to ignite and maintain a plasma 160 in the plasma processing chamber 110 while reducing or eliminating radial plasma non-uniformity. The showerhead 108 and top electrode 112 may absorb some power from the slot antenna plate 150 if the medium between them is a dielectric.

In some embodiments, the operating frequency range for the RF bias power is 0.01 Hz to 10 GHz. While only one bias RF power source is illustrated in FIG. 1, more than one bias RF power source(s) may be used in various embodiments, for example, to provide a low frequency bias RF power and a high frequency bias RF power at the same time and enable changing the bias RF frequency more rapidly.

In addition, embodiments of the present invention may be also applied to remote plasma systems as well as batch systems. For example, the substrate holder may be able to support a plurality of wafers that are spun around a central axis as they pass through different plasma zones. Accordingly, it is possible to have multiple plasma zones, for example, including a metal-containing plasma zone, metal-free plasma zone, and plasma-free zone (e.g., a purge zone). Example embodiments of the disclosure are summarized here. Other embodiments can also be understood from the entirety of the specification as well as the claims filed herein.

FIG. 1B illustrates an example plasma processing system 20, in accordance with various embodiments. The plasma processing system 20 is similar to the plasma processing system 10 as described above with respect to FIG. 1B, with the addition that the top electrode 112 is coupled to power rather than to a ground terminal. As illustrated by FIG. 1B, the top electrode 112 is coupled to an RF source 202 through a power transmission line 206, such as a coaxial cable or the like, and a matching network 203 (also referred to as a matching box). In some embodiments, the matching network 203 is disposed on top of the insulating structure 140. In other embodiments, the top electrode is coupled to a same RF source 102 as the slot antenna plate 150, such as through a same matching network 103 or through respective matching networks 103 and 203 for each of the slot antenna plate 150 and the top electrode 112.

FIGS. 2A, 2B, and 2C illustrate various views of a slot antenna plate 150, in accordance with some embodiments. FIG. 2A illustrates a top view of a slot antenna plate 150 showing slots 154 (also referred to as cutouts) extending through a conductive ring 152. The conductive ring 152 may be a plate of conductive material that has a ring shape in a top view. In some embodiments, the slots 154 are filled with air at normal atmospheric pressure. In other embodiments, the slots 154 are filled with vacuum or a solid dielectric material (e.g., alumina, a plastic material, or the like). Although eight slots 154 are illustrated in FIG. 2A, it should be appreciated the number of slots 154 and the type of slots 154 (e.g., slots in the shape of Archimedean spirals) are non-limiting, and additional slots 154 and/or types of slots 154 may similarly be employed. In various embodiments, the slots 154 have discrete axial symmetry to generate an azimuthally symmetric plasma 160 (see above, FIG. 1A).

FIG. 2B illustrates a perspective view of the slot antenna plate 150 mounted in an insulating structure 140, in accordance with some embodiments. Although the insulating structure 140 is illustrated as a wireframe model, it comprises a solid material (e.g., alumina) in various embodiments. A conduction line 148 couples the slot antenna plate 150 to RF power (e.g., from an RF source 102; see above, FIG. 1A) through a sidewall of the insulating structure 140. Coupling power through the conduction line 148 to the slot antenna plate 150 may be advantageous for reducing radial plasma non-uniformity. FIG. 2C illustrates another perspective view of the slot antenna plate 150 mounted in an insulating structure 140 from a lower point of view than the perspective view illustrated in FIG. 2B. It should be understood that slots 154 may be present in the slot antenna plate 150 despite being omitted for simplicity of illustration in FIG. 2C.

The slot antenna plate 150 may be manufactured by one or more manufacturing techniques, such as machining, casting, etching, electroforming, 3D metal printing, or a combination thereof. Different manufacturing techniques may provide different benefits such as desired plate thickness of the slot antenna plate 150, materials or coatings used, and properties such as shape, weight, thermal expansion, or the like.

In some embodiments, the slot antenna plate 150 is manufactured by a machining process. Machining is used to cut a metal plate to a desired thickness and remove portions to form a desired pattern (e.g., a pattern of a radiating structure illustrated in FIG. 2A). In some embodiments, a slot antenna plate 150 formed by machining may have a thickness in a range of 0.1 mm to 20 mm, and the slot antenna plate 150 may be mounted on a dielectric support structure (e.g., the insulating structure 140; see above, FIG. 1A) to provide augmented mechanical rigidity. The dielectric support structure may also act as a wavelength shrinking medium.

In some embodiments, machining is used to form the slot antenna plate 150 from copper or copper alloy. Using copper or copper alloy for the machining process can provide a slot antenna plate 150 with a precise shape and high conductivity. In some embodiments, machining is used to form the slot antenna plate 150 from aluminum or aluminum alloy. Using aluminum or aluminum alloy for the machining process may provide a slot antenna plate 150 with a precise shape and low weight due to the low density of aluminum. For example, the specific density of the slot antenna plate material may be in a range of 2.6 to 2.8 g/cm³.

In some embodiments, machining is used to form the slot antenna plate 150 from iron-nickel alloy or iron-nickel-cobalt alloy. Using iron-nickel alloy or iron-nickel-cobalt alloy for the machining process may provide a slot antenna plate 150 with a precise shape and low thermal expansion, such as a thermal expansion in a range of 10×10⁻⁶ m/(m-C) to 15×10⁻⁶ m/(m-C), or in a range of 0/K to 5×10⁻⁶/K. Additionally, using iron-nickel alloy or iron-nickel-cobalt alloy for the machining process may allow for a plating of the slot antenna plate 150 with, for example, a gold, silver, or nickel coating to be applied with a suitable technique such as electroplating or electroless plating.

In some embodiments, the slot antenna plate 150 is manufactured by a casting process. Molten metal is poured into a mold with a desired pattern to form a radiating structure with a desired shape (e.g., a pattern of a radiating structure illustrated in FIG. 2A). Casting may be less expensive than other manufacturing techniques such as machining, etching, electroforming, or the like. In some embodiments, a slot antenna plate 150 formed by casting may have a thickness in a range of 3 mm to 25 mm, and the slot antenna plate 150 may be mounted on a dielectric support structure to provide augmented mechanical rigidity.

In some embodiments, casting is used to form the slot antenna plate 150 from copper alloy. Using copper alloy for the casting process may provide a slot antenna plate 150 for low cost and with high conductivity, such as the conductivity described above with respect to a radiating structure formed using machining on copper alloy.

In some embodiments, casting is used to form the slot antenna plate 150 from aluminum alloy. Using aluminum alloy for the casting process may provide a slot antenna plate 150 for low cost and with low weight due to the low density of aluminum, such as the weight described above with respect to a radiating structure formed using machining on aluminum or aluminum alloy.

In some embodiments, casting is used to form the slot antenna plate 150 from iron-nickel alloy or iron-nickel-cobalt alloy. Using iron-nickel alloy or iron-nickel-cobalt alloy for the casting process may provide a slot antenna plate 150 for low cost and with low thermal expansion, such as the thermal expansion described above with respect to a radiating structure formed using machining on iron-nickel alloy or iron-nickel-cobalt alloy. Additionally, using iron-nickel alloy or iron-nickel-cobalt alloy for the casting process may allow for a plating of the slot antenna plate 150 with, for example, a gold, silver, or nickel coating to be applied with a suitable technique such as electroplating or electroless plating.

In some embodiments, the slot antenna plate 150 is manufactured by an etching process. A desired pattern to form a radiating structure with a desired shape (e.g., a pattern of a radiating structure illustrated in FIG. 2A) is printed onto a photoresist (e.g., by exposure to light) over a thin metal plate. The areas of the photoresist not exposed are removed to expose regions of the metal plate, and the exposed regions of the metal plate are then removed with a suitable etchant (e.g., a wet etch with an acidic solution). Etching may be useful for forming a thinner radiating structure than other manufacturing techniques such as machining, casting, electroforming, or the like. In some embodiments, a slot antenna plate 150 formed by etching may have a thickness in a range of 0.1 mm to 2 mm, and the slot antenna plate 150 is mounted on a dielectric support structure (e.g., the insulating structure 140; see above, FIG. 1A) to provide mechanical rigidity.

In some embodiments, etching is used to form the slot antenna plate 150 from copper alloy. Using copper alloy for the etching process may provide a slot antenna plate 150 with smaller thickness and high conductivity, such as the conductivity described above with respect to a radiating structure formed using machining on copper or copper alloy.

In some embodiments, etching is used to form the slot antenna plate 150 from aluminum alloy. Using aluminum alloy for the etching process may provide a slot antenna plate 150 with smaller thickness and low weight due to the low density of aluminum, such as the weight described above with respect to a radiating structure formed using machining on aluminum or aluminum alloy.

In some embodiments, etching is used to form the slot antenna plate 150 from iron-nickel alloy or iron-nickel-cobalt alloy. Using iron-nickel alloy or iron-nickel-cobalt alloy for the etching process may provide a slot antenna plate 150 with smaller thickness and low thermal expansion, such as the thermal expansion described above with respect to a radiating structure formed using machining on iron-nickel alloy or iron-nickel-cobalt alloy. Additionally, using iron-nickel alloy or iron-nickel-cobalt alloy for the etching process may allow for a plating of the slot antenna plate 150 with, for example, a gold, silver, or nickel coating to be applied with a suitable technique such as electroplating or electroless plating.

In some embodiments, the slot antenna plate 150 is manufactured by an electroforming process. In electroforming, a desired thickness of a metal is electrodeposited on a conductive model with a desired shape (e.g., a pattern of a radiating structure illustrated in FIGS. 2-6). In some embodiments, the conductive model is formed by manufacturing a desired shape out of a non-conductive material (e.g., plastic, glass, or the like) and then depositing a conductive layer on the non-conductive material. The conductive layer may be deposited chemically, with a vacuum deposition technique such as sputtering or the like. After the desired thickness of the metal is electrodeposited on the conductive model to form the slot antenna plate 150, the conductive model is removed from the electroformed slot antenna plate 150 with a mechanical or chemical parting method. In some embodiments, a slot antenna plate 150 formed by machining may have a thickness in a range of 0.1 mm to 3 mm, and the slot antenna plate 150 may be mounted on a dielectric support structure to provide augmented mechanical rigidity.

In some embodiments, electroforming is used to form the slot antenna plate 150 with copper alloy. This may provide a slot antenna plate 150 with smaller thickness, precise shape, and high conductivity, such as the conductivity described above with respect to a radiating structure formed using machining on copper or copper alloy.

In some embodiments, electroforming is used to form the slot antenna plate 150 with aluminum alloy. This may provide a slot antenna plate 150 with smaller thickness, precise shape, and low weight due to the low density of aluminum, such as the weight described above with respect to a radiating structure formed using machining on aluminum or aluminum alloy.

In some embodiments, electroforming is used to form the slot antenna plate 150 with iron-nickel alloy or iron-nickel-cobalt alloy. This may provide a slot antenna plate 150 with smaller thickness, precise shape, and low thermal expansion, such as the thermal expansion described above with respect to a radiating structure formed using machining on iron-nickel alloy or iron-nickel-cobalt alloy. Additionally, forming iron-nickel alloy or iron-nickel-cobalt alloy with the electroforming process may allow for a plating of the slot antenna plate 150 with, for example, a gold, silver, or nickel coating to be applied with a suitable technique such as electroplating or electroless plating.

In some embodiments, the slot antenna plate 150 is manufactured by a 3D metal printing process. 3D metal printing may enable complexity in the pattern of the slot antenna plate 150 without increasing costs, such as for making cooling channels in the slot antenna plate 150.

FIG. 3 illustrates simulated results for sheath electric field for a plasma generated with a plasma processing system 10 having a slot antenna plate 150, in accordance with some embodiments. As illustrated by FIG. 3, no significant mode pattern is present in the sheath electric field. This may reduce radial plasma non-uniformity, thereby improving uniformity of treatment of a substrate with the plasma.

FIGS. 4A and 4B illustrate graphs of simulated results for plasma permittivity at a pressure of 100 mTorr in plasma processing chambers without a slot antenna plate (FIG. 4A) and with a slot antenna plate (FIG. 4B), respectively, in accordance with some embodiments. FIGS. 4A and 4B plot the input reflection coefficients |S₁₁| versus RF power frequency for plasmas with numbers of electrons at 10¹⁶, 10^{16.5}, and 10¹⁷. As illustrated by FIG. 4B, the plasmas generated in a plasma processing chamber with a slot antenna plate may have good transmission at an RF power frequency in a range of 160 MHz to 240 MHz.

FIG. 5 illustrates a process flow chart diagram of a method 500 for plasma processing, in accordance with some embodiments. In step 502, RF power is coupled to a slot antenna plate mounted in an insulating structure, as described above with respect to FIG. 1A. The insulating structure is a top portion of a plasma processing chamber. In step 504, a plasma is ignited in the plasma processing chamber with the RF power coupled through the slot antenna plate, as described above with respect to FIG. 1A. In step 506, a substrate is processed with the plasma, as described above with respect to FIG. 1A.

Example embodiments of the disclosure are summarized here. Other embodiments can also be understood from the entirety of the specification as well as the claims filed herein.

Example 1. An apparatus for plasma processing, the apparatus including: an insulating structure including a showerhead; and an antenna surrounding the showerhead, the antenna including: a plate of conductive material, the plate having a ring shape in a top view; and a first slot through the plate of conductive material, the first slot having a longitudinal length that is a half wavelength of an excited frequency electromagnetic wave in a range of 160 MHz to 240 MHz.

Example 2. The apparatus of example 1, where the antenna further includes a second slot through an eighth slot.

Example 3. The apparatus of example 2, where the first slot through the eighth slot have discrete axial symmetry.

Example 4. The apparatus of one of examples 2 or 3, where the first slot through the eighth slot are filled with a dielectric.

Example 5. The apparatus of example 4, where the dielectric is air at atmospheric pressure.

Example 6. The apparatus of example 4, where the dielectric is vacuum.

Example 7. The apparatus of example 4, where the dielectric is a solid dielectric material.

Example 8. The apparatus of one of examples 1 to 7, where the antenna is coupled to a power source, the power source being configured to supply VHF range power.

Example 9. An apparatus for a plasma processing system, the apparatus including: a plasma processing chamber, the plasma processing chamber including: a substrate holder; a showerhead, the showerhead being over the substrate holder; an insulating structure, the insulating structure covering the showerhead; and a slot antenna plate, the slot antenna plate being mounted in the insulating structure, the slot antenna plate including a plurality of slots extending through the slot antenna plate; and a first radio frequency (RF) source, the first RF source coupled to the slot antenna plate through a sidewall of the insulating structure.

Example 10. The apparatus of example 9, where the insulating structure includes aluminum oxide.

Example 11. The apparatus of one of examples 9 or 10, further including a vacuum seal disposed between the slot antenna plate and the showerhead.

Example 12. The apparatus of example 11, where the vacuum seal is an O-ring.

Example 13. The apparatus of one of examples 9 to 12, where the plurality of slots are filled with air at atmospheric pressure.

Example 14. The apparatus of one of examples 9 to 13, where each slot of the plurality of slots has a respective longitudinal length that is a half wavelength of an excited frequency electromagnetic wave in the insulating structure.

Example 15. The apparatus of one of examples 9 to 14, where the plurality of slots includes eight slots.

Example 16. The apparatus of one of examples 9 to 15, further including a top electrode over the showerhead.

Example 17. The apparatus of example 16, where the top electrode is coupled to a ground terminal.

Example 18. The apparatus of example 16, where the top electrode is coupled to a second RF source.

Example 19. A method for plasma processing, the method including: coupling RF power to a slot antenna plate mounted in an insulating structure, the insulating structure being a top portion of a plasma processing chamber; igniting a plasma in the plasma processing chamber with the RF power coupled through the slot antenna plate; and processing a substrate with the plasma.

Example 20. The method of example 19, where the RF power has a frequency in a range of 160 MHz to 240 MHz.

Example 21. The method of one of examples 19 or 20, where the slot antenna plate includes a plurality of slots, each slot of the plurality of slots having a respective longitudinal length that is a half wavelength of an excited frequency electromagnetic wave in the insulating structure.

Example 22. An antenna for plasma processing, the antenna including: a plate of conductive material, the plate having a ring shape in a top view; and a first slot through the plate of conductive material, the first slot having a longitudinal length that is a half wavelength of an excited frequency electromagnetic wave in a range of 160 MHz to 240 MHz.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An apparatus for plasma processing, the apparatus comprising:
an insulating structure comprising a showerhead; and
an antenna surrounding the showerhead, the antenna comprising:
a plate of conductive material, the plate having a ring shape in a top view; and
a first slot through the plate of conductive material, the first slot having a longitudinal length that is a half wavelength of an excited frequency electromagnetic wave in a range of 160 MHz to 240 MHz.

2. The apparatus of claim 1, wherein the antenna further comprises a second slot through an eighth slot.

3. The apparatus of claim 2, wherein the first slot through the eighth slot have discrete axial symmetry.

4. The apparatus of claim 2, wherein the first slot through the eighth slot are filled with a dielectric.

5. The apparatus of claim 4, wherein the dielectric is air at atmospheric pressure.

6. The apparatus of claim 4, wherein the dielectric is vacuum.

7. The apparatus of claim 4, wherein the dielectric is a solid dielectric material.

8. The apparatus of claim 1, wherein the antenna is coupled to a power source, the power source being configured to supply VHF range power.

9. An apparatus for a plasma processing system, the apparatus comprising:
a plasma processing chamber, the plasma processing chamber comprising:
a substrate holder;
a showerhead, the showerhead being over the substrate holder;
an insulating structure, the insulating structure covering the showerhead; and
a slot antenna plate, the slot antenna plate being mounted in the insulating structure, the slot antenna plate comprising a plurality of slots extending through the slot antenna plate; and
a first radio frequency (RF) source, the first RF source coupled to the slot antenna plate through a sidewall of the insulating structure.

10. The apparatus of claim 9, wherein the insulating structure comprises aluminum oxide.

11. The apparatus of claim 9, further comprising a vacuum seal disposed between the slot antenna plate and the showerhead.

12. The apparatus of claim 8, wherein the plurality of slots are filled with air at atmospheric pressure.

13. The apparatus of claim 8, wherein each slot of the plurality of slots has a respective longitudinal length that is a half wavelength of an excited frequency electromagnetic wave in the insulating structure.

14. The apparatus of claim 8, wherein the plurality of slots comprises eight slots.

15. The apparatus of claim 8, further comprising a top electrode over the showerhead.

16. The apparatus of claim 15, wherein the top electrode is coupled to a ground terminal.

17. The apparatus of claim 15, wherein the top electrode is coupled to a second RF source.

18. A method for plasma processing, the method comprising:
coupling RF power to a slot antenna plate mounted in an insulating structure, the insulating structure being a top portion of a plasma processing chamber;
igniting a plasma in the plasma processing chamber with the RF power coupled through the slot antenna plate; and
processing a substrate with the plasma.

19. The method of claim 18, wherein the RF power has a frequency in a range of 160 MHz to 240 MHz.

20. The method of claim 18, wherein the slot antenna plate comprises a plurality of slots, each slot of the plurality of slots having a respective longitudinal length that is a half wavelength of an excited frequency electromagnetic wave in the insulating structure.
